(19) United States
(12) Patent Application Publication
(10) Pub. No.: US 2015/0009290 A1
(43) Pub. Date: Jan. 8, 2015

(54) COMPACT LIGHT MODULE FOR STRUCTURED-LIGHT 3D SCANNING

(71) Applicants: Peter MANKOWSKI, Waterloo (CA); Yaran NAN, Kitchener (CA)

(72) Inventors: Peter MANKOWSKI, Waterloo (CA); Yaran NAN, Kitchener (CA)

(21) Appl. No.: 13/936,017

(22) Filed: Jul. 5, 2013

(51) Int. Cl. H04N 5/235; H04N 13/02; H01L 33/58

(52) U.S. Cl. CPC H04N 5/2354; H01L 33/58; H04N 13/0203
USPC 348/46; 257/76

(57) ABSTRACT

A compact light module is disclosed. Multiples of such compact light modules may be used when implementing structured-light 3D scanning with a mobile computing device. In particular, a first compact light module may be adapted to diffuse light in a first pattern of parallel lines of light and a second compact light module may be adapted to diffuse light in a second pattern of parallel lines of light, the second pattern of parallel lines of light being generally perpendicular to the first pattern of parallel lines of light. A processor may control activation of the first compact light module, the second compact light module and a photography subsystem to obtain a plurality of images. The processor may then process the plurality of images to construct a three dimensional image of an object to be scanned.

### FIELD

The present application relates generally to three dimensional scanning for a mobile computing device and, more specifically, to a compact light module and structured-light 3D scanning using multiple such compact light modules.

### BACKGROUND

As mobile telephones have received increasing amounts of computing power in successive generations, the mobile telephones have been termed “smart phones.” Along with increasing amounts of computing power, such smart phones have seen increases in storage capacity, processor speed and networking speed. Consequently, smart phones have been seen to have increased utility. Beyond telephone functions, smart phones may now send and receive digital messages, be they formatted to use e-mail standards, Short Messaging Service (SMS) standards, Instant Messaging standards and proprietary messaging systems. Smart phones may also store, read, edit and create documents, spreadsheets and presentations. Accordingly, there have been increasing demands for smart phones with enhanced authentication functions.

### BRIEF DESCRIPTION OF THE DRAWINGS

Reference will now be made, by way of example, to the accompanying drawings which show example implementations; and in which:

FIG. 1 illustrates an anterior side of a mobile communication device;

FIG. 2 illustrates an example arrangement of internal components of the mobile communication device of FIG. 1;

FIG. 3 illustrates a posterior side of the mobile communication device of FIG. 1, the posterior side including a primary posterior LED under a primary cover lens, a secondary posterior LED under a secondary cover lens and a photography subsystem under a posterior lens;

FIG. 4 illustrates example steps in a method of obtaining a 3D scan of an object to be scanned;

FIG. 5 illustrates an example timing of activation for the primary posterior LED, the secondary posterior LED and the photography subsystem of FIG. 3; and

FIG. 6 illustrates a mechanical stack of components suitable for serving as the combination of the primary posterior LED and the primary cover lens and/or the combination of the secondary posterior LED and the secondary cover lens of FIG. 3.

### DETAILED DESCRIPTION

A compact light module is disclosed. Multiples of such compact light modules may be used when implementing structured-light 3D scanning with a mobile computing device. In particular, a first compact light module may be adapted to diffuse light in a first light pattern, e.g., parallel lines of light or collimated light, and a second compact light module may be adapted to diffuse light in a second light pattern, e.g., parallel lines of light or collimated light, the second light pattern being offset, e.g., transverse or generally perpendicular, to the first light pattern. A processor may control activation of the first compact light module, the second compact light module and a photography subsystem to obtain a plurality of images. The processor may then process the plurality of images to construct a three dimensional image of an object to be scanned.

According to an aspect of the present disclosure, there is provided a mobile communication device comprising a lens, a photography subsystem positioned to capture images through the lens, a first light emitting diode (LED) module, the first LED module including a first LED and a first top cover, the first top cover adapted to diffuse light generated by the first LED in a first pattern of collimated light, a second LED module, the second LED module including a second LED and a second top cover, the second top cover adapted to diffuse light generated by the second LED in a second pattern of collimated light, the second pattern being offset from the first pattern and an image signal processor. The image signal processor may be adapted to control activation of the first LED module, the second LED module and the photography subsystem to obtain a plurality of images and process the plurality of images to construct a three dimensional image of an object to be scanned.

According to another aspect of the present disclosure, there is provided a method of obtaining a three dimensional image of an object to be scanned. The method includes sending an instruction to activate a first light source to illuminate the object to be scanned with a first pattern of collimated light, sending an instruction to a photography subsystem to obtain a first image of the object to be scanned as illuminated by the first light source, receiving, from the photography subsystem, the first image, sending an instruction to activate a second light source to illuminate the object to be scanned with a second pattern of collimated light, the second pattern of collimated light being offset from the first pattern of collimated light, sending an instruction to the photography subsystem to obtain a second image of the object to be scanned as illuminated by the second light source, receiving, from the photography subsystem, the second image and constructing a three-dimensional image from the first image and the second image. In other aspects of the present application, a computer readable medium is provided for adapting a processor to carry out this method.

According to another aspect of the present disclosure, there is provided a light emitting diode (LED) module comprising a main module body adapted to emit light, a low angle lens arranged to focus the light from the main module body to a light beam and a top cover adapted to diffuse the light beam in a pattern of collimated light.

Other aspects and features of the present disclosure will become apparent to those of ordinary skill in the art upon review of the following description of specific implementations of the disclosure in conjunction with the accompanying figures.

Especially as three dimensional (3D) printing becomes increasingly available, the ability to capture a three-dimensional image is becoming correspondingly in demand. There are a wide variety of 3D scanners on the market today. A typical 3D scanner, however, is relatively large and is marketed as an accessory to a pre-existing computer system, such as a desktop computer or a notebook computer.

In overview, device components are described herein sized for inclusion in a smart phone or tablet, thereby allowing the smart phone or tablet to obtain 3D images.

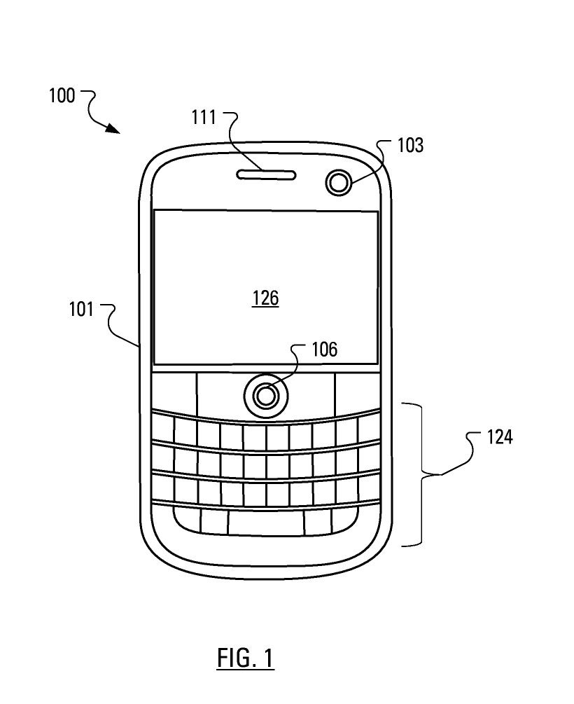

FIG. 1 illustrates an anterior side of a mobile communication device 100. Many features of the anterior side of the mobile communication device 100 are mounted within a housing 101 and include a display 126, a keyboard 124 having a plurality of keys, a speaker 111, a navigation device 106 (e.g., a touchpad, a trackball, a touchscreen, an optical navigation module) and an anterior (user-facing) lens 103A.

The anterior side of the mobile communication device 100 includes an anterior Light Emitting Diode (LED) 107A for use as a flash when using the mobile communication device 100 to capture, through the anterior lens 103A, a still photograph.

The mobile communication device 100 includes an input device (e.g., the keyboard 124) and an output device (e.g., the display 126), which may comprise a full graphic, or full color, Liquid Crystal Display (LCD). In some implementations, the display 126 may comprise a touchscreen display. In such touchscreen implementations, the keyboard 124 may comprise a virtual keyboard provided on the display 126. Other types of output devices may alternatively be utilized.

The housing 101 may be elongated vertically, or may take on other sizes and shapes (including clamshell housing structures or touch screen only structures). In the case in which the keyboard 124 includes keys that are associated with at least one alphabetic character and at least one numeric character, the keyboard 124 may include a mode selection key, or other hardware or software, for switching between alphabetic entry and numeric entry.

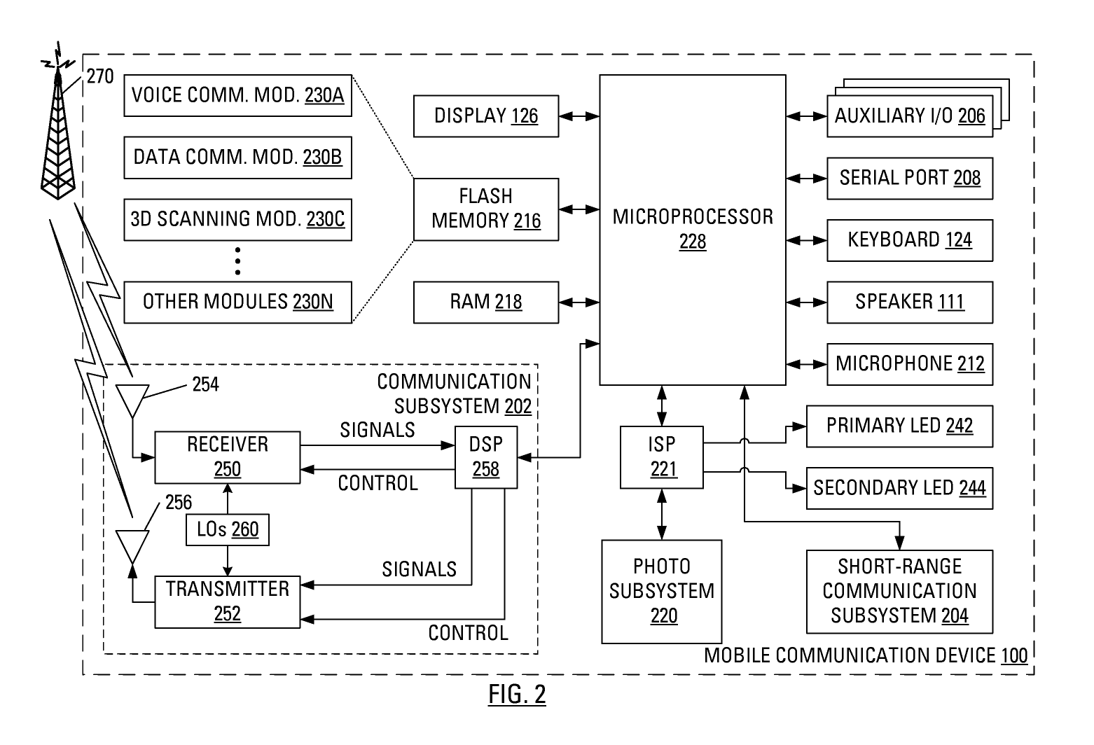

FIG. 2 illustrates an example arrangement of internal components of the mobile communication device 100. A processing device (a microprocessor 228) is shown schematically in FIG. 2 as coupled between the keyboard 124 and the display 126. The microprocessor 228 controls the operation of the display 126, as well as the overall operation of the mobile communication device 100, in part, responsive to actuation of the keys on the keyboard 124 by a user.

In addition to the microprocessor 228, other parts of the mobile communication device 100 are shown schematically in FIG. 2. These may include a communications subsystem 202, a short-range communications subsystem 204, the keyboard 124 and the display 126. The mobile communication device 100 may further include other input/output devices, such as a set of auxiliary I/O devices 206, a serial port 208, the speaker 111 and a microphone 212. The mobile communication device 100 may further include memory devices including a flash memory 216 and a Random Access Memory (RAM) 218 as well as various other device subsystems. The mobile communication device 100 may comprise a two-way, radio frequency (RF) communication device having voice and data communication capabilities. In addition, the mobile communication device 100 may have the capability to communicate with other computer systems via the Internet.

Operating system software executed by the microprocessor 228 may be stored in a computer readable medium, such as the flash memory 216, but may be stored in other types of memory devices, such as a read only memory (ROM) or similar storage element. In addition, system software, specific device applications, or parts thereof, may be temporarily loaded into a volatile store, such as the RAM 218. Communication signals received by the mobile device may also be stored to the RAM 218.

The microprocessor 228, in addition to its operating system functions, enables execution of software applications on the mobile communication device 100. A predetermined set of modules that control basic device operations, such as a voice communications module 230A and a data communications module 230B, may be installed on the mobile communication device 100 during manufacture. A 3D scanning module 230C may also be installed on the mobile communication device 100 during manufacture, to implement aspects of the present disclosure. As well, additional software modules, illustrated as another module 230N, which may be, for instance, a PIM application, may be installed during manufacture. The PIM application may be capable of organizing and managing data items, such as e-mail messages, calendar events, voice mail messages, appointments and task items. The PIM application may also be capable of sending and receiving data items via a wireless carrier network 270 represented by a radio tower. The data items managed by the PIM application may be seamlessly integrated, synchronized and updated via the wireless carrier network 270 with the device user's corresponding data items stored or associated with a host computer system.

These modules 230A, 230B, 230C, 230N may, for one example, comprise a combination of hardware (say, a dedicated processor, not shown) and software (say, a software application arranged for execution by the dedicated processor) or may, for another example, comprise a software application arranged for execution by the microprocessor 228.

Communication functions, including data and voice communications, are performed through the communication subsystem 202 and, possibly, through the short-range communications subsystem 204. The communication subsystem 202 includes a receiver 250, a transmitter 252 and one or more antennas, illustrated as a receive antenna 254 and a transmit antenna 256. In addition, the communication subsystem 202 also includes a processing module, such as a digital signal processor (DSP) 258, and local oscillators (LOs) 260. The specific design and implementation of the communication subsystem 202 is dependent upon the communication network in which the mobile communication device 100 is intended to operate. For example, the communication subsystem 202 of the mobile communication device 100 may be designed to operate with the Mobitex™, DataTAC™ or General Packet Radio Service (GPRS) mobile data communication networks and also designed to operate with any of a variety of voice communication networks, such as Advanced Mobile Phone Service (AMPS), Time Division Multiple Access (TDMA), Code Division Multiple Access (CDMA), Personal Communications Service (PCS), Global System for Mobile Communications (GSM), Enhanced Data rates for GSM Evolution (EDGE), Universal Mobile Telecommunications System (UMTS), Wideband Code Division Multiple Access (W-CDMA), High Speed Packet Access (HSPA), etc. Other types of data and voice networks, both separate and integrated, may also be utilized with the mobile communication device 100.

Network access requirements vary depending upon the type of communication system. Typically, an identifier is associated with each mobile device that uniquely identifies the mobile device or subscriber to which the mobile device has been assigned. The identifier is unique within a specific network or network technology. For example, in Mobitex™ networks, mobile devices are registered on the network using a Mobitex Access Number (MAN) associated with each device and in DataTAC™ networks, mobile devices are registered on the network using a Logical Link Identifier (LLI) associated with each device. In GPRS networks, however, network access is associated with a subscriber or user of a device. A GPRS device therefore uses a subscriber identity module, commonly referred to as a Subscriber Identity Module (SIM) card, in order to operate on a GPRS network. Despite identifying a subscriber by SIM, mobile devices within GSM/GPRS networks are uniquely identified using an International Mobile Equipment Identity (IMEI) number.

When required network registration or activation procedures have been completed, the mobile communication device 100 may send and receive communication signals over the wireless carrier network 270. Signals received from the wireless carrier network 270 by the receive antenna 254 are routed to the receiver 250, which provides for signal amplification, frequency down conversion, filtering, channel selection, etc., and may also provide analog to digital conversion. Analog-to-digital conversion of the received signal allows the DSP 258 to perform more complex communication functions, such as demodulation and decoding. In a similar manner, signals to be transmitted to the wireless carrier network 270 are processed (e.g., modulated and encoded) by the DSP 258 and are then provided to the transmitter 252 for digital to analog conversion, frequency up conversion, filtering, amplification and transmission to the wireless carrier network 270 (or networks) via the transmit antenna 256.

In addition to processing communication signals, the DSP 258 provides for control of the receiver 250 and the transmitter 252. For example, gains applied to communication signals in the receiver 250 and the transmitter 252 may be adaptively controlled through automatic gain control algorithms implemented in the DSP 258.

In a data communication mode, a received signal, such as a text message or web page download, is processed by the communication subsystem 202 and is input to the microprocessor 228. The received signal is then further processed by the microprocessor 228 for output to the display 126, or alternatively to some auxiliary I/O devices 206. A device user may also compose data items, such as e-mail messages, using the keyboard 124 and/or some other auxiliary I/O device 206, such as the navigation device 106, a touchpad, a rocker switch, a thumb-wheel, a trackball, a touchscreen, or some other type of input device. The composed data items may then be transmitted over the wireless carrier network 270 via the communication subsystem 202.

In a voice communication mode, overall operation of the device is substantially similar to the data communication mode, except that received signals are output to the speaker 111, and signals for transmission are generated by a microphone 212. Alternative voice or audio I/O subsystems, such as a voice message recording subsystem, may also be implemented on the mobile communication device 100. In addition, the display 126 may also be utilized in voice communication mode, for example, to display the identity of a calling party, the duration of a voice call, or other voice call related information.

The short-range communications subsystem 204 enables communication between the mobile communication device 100 and other proximate systems or devices, which need not necessarily be similar devices. For example, the short-range communications subsystem may include an infrared device and associated circuits and components, or a Bluetooth™ communication module to provide for communication with similarly-enabled systems and devices.

A photography subsystem 220 connects to the microprocessor 228 via an Image Signal Processor (ISP) 221. Indeed, the photography subsystem 220 includes a communication interface (not shown) for managing communication with the ISP 221.

The mobile communication device 100 also includes a primary posterior LED 242 and a secondary posterior LED 244, both in communication with the ISP 221.

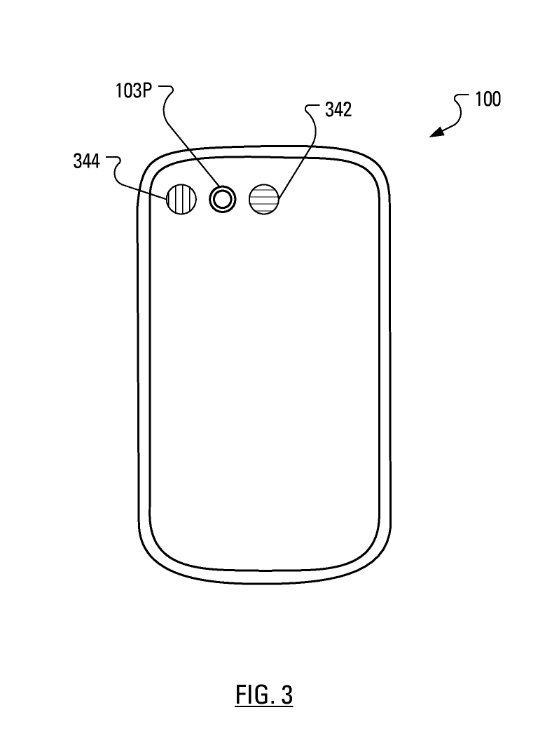

FIG. 3 illustrates a posterior side of the mobile communication device 100. Included on the posterior side are a posterior lens 103P, a primary cover lens 342 and a secondary cover lens 344. The light output by the primary posterior LED 242 is modified with the primary cover lens 342. The primary cover lens 342 implements a grating such that the light output from the primary cover lens 342 is a plurality of lines of light at a first orientation relative to one another, for example, parallel. The light output by the secondary posterior LED 244 is modified with the secondary cover lens 344. The secondary cover lens 344 implements a grating such that the light output from the secondary cover lens 344 is a plurality of lines of light at a second orientation relative to one another, for example, parallel. The plurality of lines of light from the secondary cover lens 344 may be arranged to be in a different orientation relative to the plurality of lines of light from the primary cover lens 342. In the case wherein the plurality of lines of light from the secondary cover lens 344 are parallel to each other, they may, for example, be arranged to be generally perpendicular to the plurality of lines of light from the primary cover lens 342, which may also be parallel to each other.

As illustrated in FIG. 3, the posterior lens 103P interposes the primary cover lens 342 and the secondary cover lens 344 and center lines of all three elements are aligned. In other arrangements, the primary cover lens 342 and the secondary cover lens 344 may be positioned closer to one another than illustrated in FIG. 3. In one such arrangement, the posterior lens 103P may be positioned so that the center line of the posterior lens 103P is above the top tangent of the primary cover lens 342 and the secondary cover lens 344, whose center lines remain aligned. In another such arrangement, the posterior lens 103P may be positioned so that the center line of the posterior lens 103P is below the bottom tangent of the primary cover lens 342 and the secondary cover lens 344, whose center lines remain aligned.

The architecture illustrated in FIGS. 2 and 3 allows for “non-contact” radiated light to be used for 3D scanning. Additionally, so-called “Structured-Light 3D Scanning” may be employed.

In structured-light 3D scanning, a scanner projects a pattern of light on a subject. Analysis of the deformation, by features of the subject, of the pattern of light allows for construction of a 3D image of the subject. The pattern of light may be projected onto the subject using a stable light source. The light source may be, for example, an LED that has been modified to have a relatively narrow projection angle. A photography subsystem may obtain images through a lens that is offset from the light source. A processor may then analyze the images.

Most LEDs are designed to project light with a projection angle that is close to 120 degrees. The “relatively narrow” term is used hereinbefore to suggest a projection angle that is less than 50 degrees at a 50% lux intensity level. Conveniently, when the projection angle and the distance between LED 242/244 and the lens 342/344 are selected with care, the lines projected by the lens 342/344 are optimized for sharpness. There is significant available flexibility when designing for specific situations. In certain conditions, it might be preferred to “flatten” the stack of components to meet specific mechanical goals. Under such conditions, the designer will consider the diameter of the lens 342/344, the distance between the LED 242/244 and lens 342/344 as well as the light projection angle of the LED 242/244.

Structured-light 3D scanning is still a very active area of research with many research papers published each year. For example, see R. Morano et al. “Structured Light Using Pseudorandom Codes,” IEEE Transactions on Pattern Analysis and Machine Intelligence, Volume 20, Issue 3, March 1998, which document is hereby incorporated herein by reference. However, if there is conflict between the document and the present disclosure, the present disclosure controls.

Advantages of structured-light 3D scanning include speed and precision. Instead of scanning one point at a time, structured light scanners scan multiple points/lines or an entire field of view at once. Scanning an entire field of view in a fraction of a second generates a profile that may be shown to be more precise than a profile generated using laser triangulation.

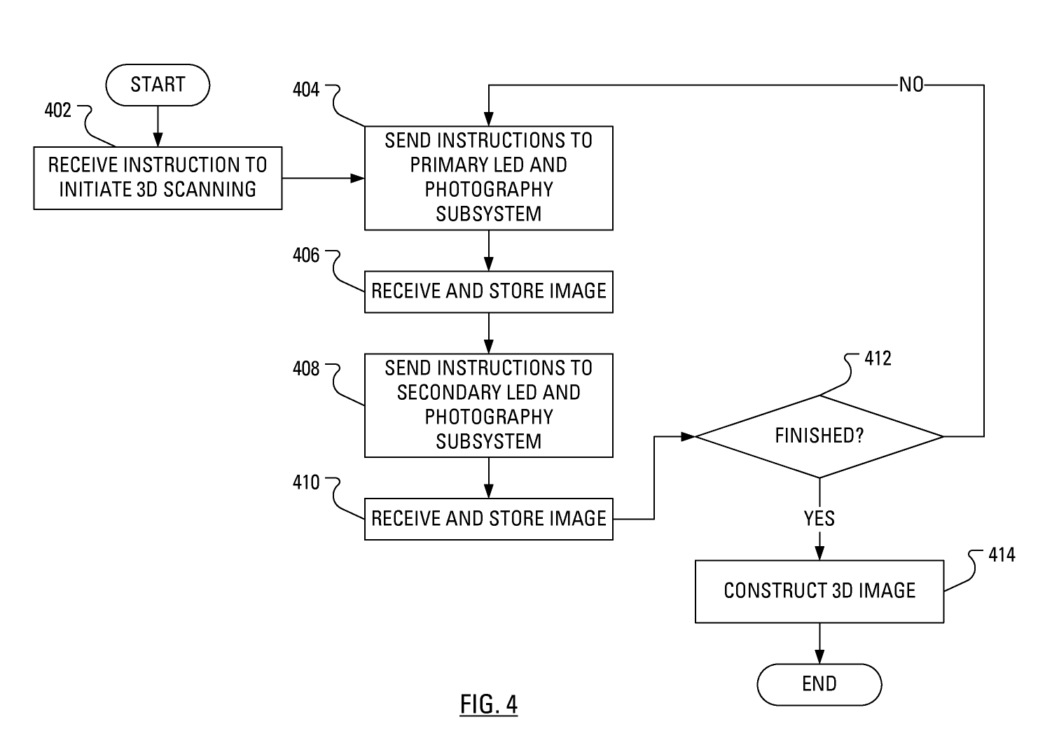

In operation, a user of the mobile communication device 100 may interact with the user interface of the mobile communication device 100 to initiate 3D scanning. FIG. 4 illustrates example steps in a method of obtaining a 3D scan of an object to be scanned. Responsive to receiving (step 402) an instruction to initiate 3D scanning, the ISP 221 may send (step 404) a flash instruction to the primary posterior LED 242 and an obtain image instruction to the photographic subsystem 220. The flash instruction may include such information as when to flash, a duration for the flash and a luminescent intensity for the flash. Upon obtaining a first image, the photographic subsystem 220 transmits the first image to the ISP 221. The ISP 221 receives and stores (step 406) the first image.

It is expected that the flash from the primary posterior LED 242 will shine through the primary cover lens 342 to illuminate areas of an object to be scanned with a plurality of parallel lines of light. These lines may be considered to expose a degree of depth in the object to be scanned.

The ISP 221 may then send (step 408) a flash instruction to the secondary posterior LED 244 and an obtain image instruction to the photographic subsystem 220. Upon obtaining a second image, the photographic subsystem 220 transmits the second image to the ISP 221. The ISP 221 receives and stores (step 410) the second image.

It is expected that the flash from the secondary posterior LED 244 will shine through the secondary cover lens 344 to illuminate areas of an object to be scanned with a plurality of parallel lines of light. These lines may be considered to expose a degree of depth in the object to be scanned.

The ISP 221 may then determine (step 412) whether enough images have been obtained. As will be understood by one skilled in the art, obtaining an image does not automatically translate into successfully capturing details of an object to be scanned. In one scenario, upon receiving an image (a RAW frame), the ISP 221 transmits the image to an application processor (not shown) for a “sanity check” of picture quality for each of the images obtained associated with one illumination of the object to be scanned. The application processor processes the received image and transmits, to the ISP 221, a so-called “frame qualifier.” The frame qualifier is a “PASS/FAIL” interrupt. If the frame qualifier indicates a PASS, the ISP 221 may determine (step 412) that enough images have been obtained. If FAIL is issued, the ISP 221 may control the LEDs 242/244 and the photographic subsystem 220 to capture two more images. Based on at least one of the original two images being insufficient, the ISP 221 may control the photographic subsystem 220 to vary (increase or decrease) one or more photographic parameters. Such parameters may include, for instance, the exposure time.

Upon receiving and storing multiple sets of obtained images, the ISP 221 processes (step 414) the images to construct a 3D image. It should be clear to a person of ordinary skill in the art that the 3D image that constructed may be expressed as a so-called “point cloud.”

When the ISP 221 processes (step 414) the images to construct a 3D image, the ISP 221 may execute an algorithm to construct an absolute phase map. Such an algorithm may, for example, receive, as input, an indication of the pattern projected upon the object to be scanned and the sets of obtained images of the object to be scanned. Subsequently, the ISP 221 may execute an algorithm for construction of the point cloud, which may receive, as input, the absolute phase map, some parameters characterizing the photographic subsystem 220 and a reference phase map. The parameters characterizing the photographic subsystem 220 may be obtained through an analysis of images of calibration artifacts.

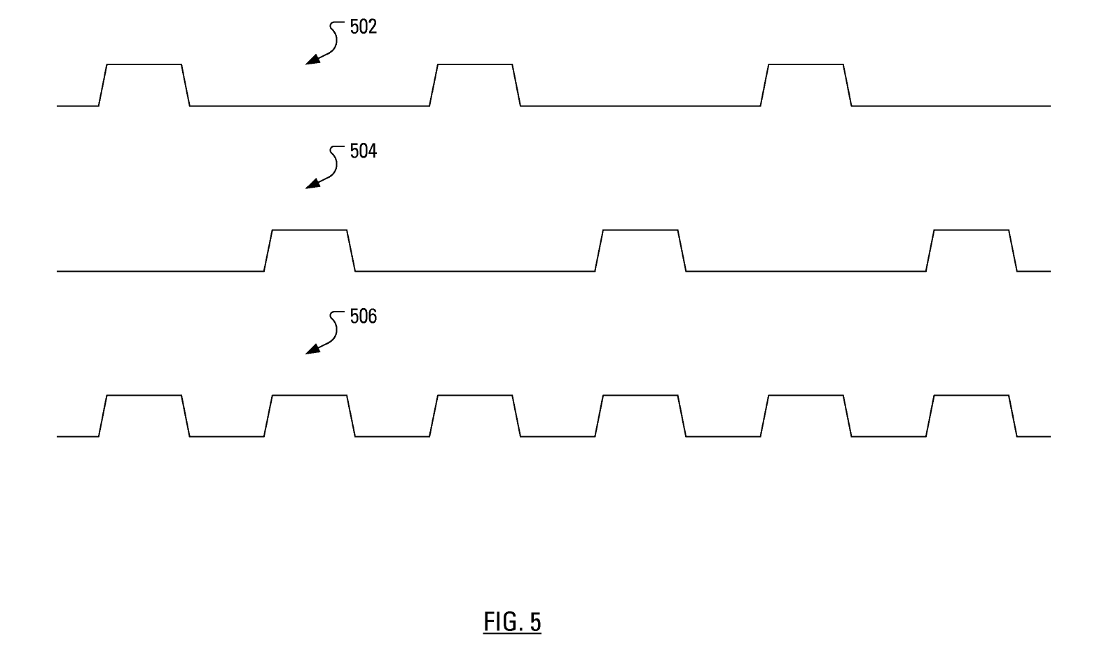

An example timing of activation for the primary posterior LED 242, the secondary posterior LED 244 and the photography subsystem 220 is illustrated in FIG. 5. A first time line 502 may be associated with the primary posterior LED 242. A second time line 504 may be associated with the secondary posterior LED 244. A third time line 506 may be associated with the photography subsystem 220. It can be seen from FIG. 5, that when the primary posterior LED 242 is active, as represented by the first time line 502 being in a high position, the photography subsystem 220 is also active, as represented by the third time line 506 being in a high position. Similarly, it can be seen from FIG. 5, that when the secondary posterior LED 244 is active, as represented by the second time line 504 being in a high position, the photography subsystem 220 is also active.

Timing of activation for the primary posterior LED 242, the secondary posterior LED 244 and the photography subsystem 220 may be distinct from the timing illustrated in FIG. 5. In FIG. 5, the timing of the activation of the primary posterior LED 242 and the secondary posterior LED 244 is evenly distributed in time. It is contemplated that the time delay between the end of activation of the primary posterior LED 242 and the beginning of activation of the secondary posterior LED 244 may have a lesser duration than the time delay between the end of activation of the secondary posterior LED 244 and the beginning of activation of the primary posterior LED 242. Indeed, in some cases, the end of activation of the primary posterior LED 242 may occur subsequent to the beginning of activation of the secondary posterior LED 244.

Obtaining a “normal” photograph with the photographic subsystem 220 may not involve activating the primary posterior LED 242 and the secondary posterior LED 244 at all, since to do so is likely to result in an image of a photographic subject illuminated by stripes of light. Accordingly, obtaining a “normal” photograph with the photographic subsystem 220 may involve activating a typical LED (not shown) as a light source or may simply involve relying on ambient light to illuminate the subject.

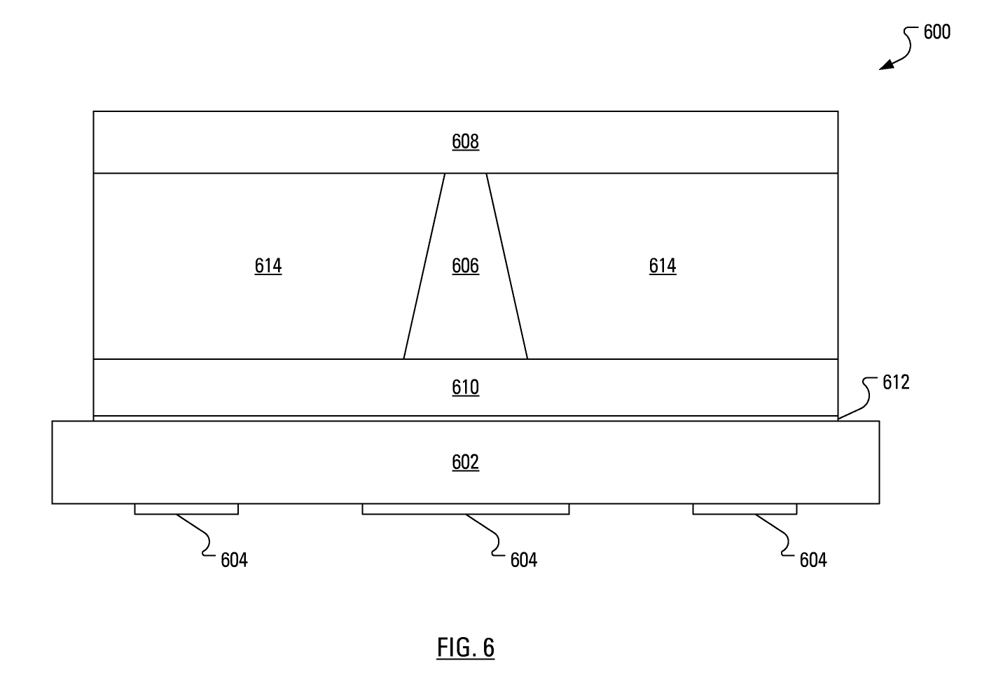

FIG. 6 illustrates a mechanical stack of components suitable for serving as the combination of the primary posterior LED 242 and the primary cover lens 342 and/or the combination of the secondary posterior LED 244 and the secondary cover lens 344.

The mechanical stack, which may be called an LED module 600, includes a main module body 602. The main module body 602 may be formed of thin Gallium Nitride (GaN), which is a semiconductor commonly used in bright LEDs. To conductively connect the main module body 602 to a circuit board (not shown), the LED module 600 may include pins 604. The LED module 600 also includes a low angle lens 606, which may be formed as a molded polymer structure supported by volume material 614. The volume material 614 may be any commercially available electronic ceramic substrate, such as Silicone Encapsulant: Siloxane LED bond (Si-O). The LED module 600 further includes a top cover 608 and a main base 610, between which the low angle lens 606 and the volume material 614 are positioned. A layer of adhesive may be used to secure the main base 610 to the main module body 602.

The top cover 608 may have 3D embedded structures. The 3D embedded structures may be used to create the plurality of lines of light described hereinbefore as being generated by the combination of the primary posterior LED 242 and the primary cover lens 342 and/or the combination of the secondary posterior LED 244 and the secondary cover lens 344.

More particularly, the 3D embedded structures may be engineered diffusers. Engineered diffusers may be defined a plurality of directional lenses embedded in a glass surface. If designed properly, the directional lenses are capable of redirecting an incident light beam, controlling the density of the light beam and the “spread angle” of the light beam. Directional lenses may be arranged to obtain a specific light effect in space and on the projected surface, such as the plurality of parallel lines of light described hereinbefore.

In operation, responsive to activation via the pins 604, the main module body 602 generates light. The light generated by the main module body 602 passes through the low angle lens 606 and is focused into a light beam. The light beam passes through the top cover 608. The 3D embedded structures of the top cover 608 diffuse the light beam to create the plurality of parallel lines of light described hereinbefore.

Conveniently, the LED module 600 may be arranged to have features such as: outstanding brightness and luminance due to pure surface emission and low Rₜₕ; a viewing angle of 20 to 25 degrees; an ability to spread light with a precise angle; and 3D patterns embedded in the top cover 608.

Some of the features of the mobile communication device 100 with the combination of the primary posterior LED 242 and the primary cover lens 342 and the combination of the secondary posterior LED 244 and the secondary cover lens 344 include: small size; low power; consumption; low cost of parts; low cost of assembly; awareness of proximity to the object being scanned; and nonintrusive operations, thereby allowing other functions to be enabled concurrently.

In one particular instance, the mobile communication device 100 may become aware of proximity to the object being scanned via the ISP 221. The ISP 221 may analyze images received from the photography subsystem 220. The ISP 221 may interpret “blurry” images as being “out-of focus” and may be configured with the focal length of the lens such that, based on the received images, an estimate of a distance from the mobile communication device 100 to a nearest point on the object being scanned.

Another manner of determining an estimate of the distance from the mobile communication device 100 to the nearest point on the object being scanned, which manner may be used in combination with other manners or alone, involves use of an ambient light sensor or “ALS” (not shown). Such an ALS may be found as standard equipment in many modern mobile communication devices. An ALS may, for example, sense a small level change in a measurement of so-called “lux” units. The ALS may then use these measurements to determine an estimate of the distance from the mobile communication device 100 to the nearest point on the object being scanned.

It is contemplated that situations in which the mobile communication device 100 with the combination of the primary posterior LED 242 and the primary cover lens 342 and the combination of the secondary posterior LED 244 and the secondary cover lens 344 may be employed include: scanning biometrics for user authentication; face recognition; hand shape 3D model; 3D shape modeling for mechanical computer aided design (CAD) industrial applications; monitoring personal fitness with weight gain/loss measurements; scanning human body parts for the purpose of selecting clothing size; and medical applications, such as scanning cancerous lumps, skin/muscle conditions and monitoring healing.

The light emitted from the first light emitter (e.g., the primary posterior LED 242) and the second light emitter (e.g., the secondary posterior LED 244) is structured to provide to different images of the same target. The light emitted sequentially illuminates the target and can be collimated light. The bands of parallel light from both emitters can be the same width. In an example, the bands of parallel light can have bands of light that have varying widths to provide finer resolution at certain regions of the target. In another example the light emitted is patterned in concentric circular or oval bands. The light patterns emitted are known to the image signal processor to properly process the plurality of images of the target that is illuminated by the structured light.

The above-described implementations of the present application are intended to be examples only. Alterations, modifications and variations may be effected to the particular implementations by those skilled in the art without departing from the scope of the application, which is defined by the claims appended hereto.

What is claimed is:

1. A mobile communication device comprising:
a lens;
a photography subsystem positioned to capture images through the lens;
a first light emitting diode (LED) module, the first LED module including a first LED and a first top cover, the first top cover adapted to diffuse light generated by the first LED in a first pattern of collimated light;
a second LED module, the second LED module including a second LED and a second top cover, the second top cover adapted to diffuse light generated by the second LED in a second pattern of collimated light, the second pattern being offset from the first pattern;
an image signal processor adapted to:
control activation of the first LED module, the second LED module and the photography subsystem to obtain a plurality of images; and
process the plurality of images to construct a three dimensional image of an object to be scanned.

2. The mobile communication device of claim 1 wherein the first LED comprises a Gallium Nitride LED.

3. The mobile communication device of claim 1 wherein the first top cover includes a plurality of directional lenses adapted to convert a light beam into the first pattern of collimated light.

4. The mobile communication device of claim 1 wherein the first LED module includes a low angle lens arranged to focus light from the first LED to a light beam incident upon the first top cover.

5. The mobile communication device of claim 1 wherein the low angle lens comprises a molded polymer structure.

6. The mobile communication device of claim 1 wherein the first pattern of collimated light comprises parallel lines of light.

7. The mobile communication device of claim 6 wherein the second pattern of collimated light comprises parallel lines of light.

8. The mobile communication device of claim 7 wherein the first pattern of parallel lines of light are generally perpendicular to the second pattern of parallel lines of light.

9. A method of obtaining a three dimensional image of an object to be scanned, the method comprising:
sending an instruction to activate a first light source to illuminate the object to be scanned with a first pattern of collimated light;
sending an instruction to a photography subsystem to obtain a first image of the object to be scanned as illuminated by the first light source;
receiving, from the photography subsystem, the first image;
sending an instruction to activate a second light source to illuminate the object to be scanned with a second pattern of collimated light;
sending an instruction to the photography subsystem to obtain a second image of the object to be scanned as illuminated by the second light source;
receiving, from the photography subsystem, the second image; and
constructing a three-dimensional image from the first image and the second image.

10. The method of claim 9 wherein the first pattern of collimated light comprises a first plurality of parallel lines of light.

11. The method of claim 10 wherein the second pattern of collimated light comprises a second plurality of parallel lines of light.

12. The method of claim 11 wherein there exists a non-zero angular offset between the second plurality of parallel lines of light and the first pattern of parallel lines of light.

13. The method of claim 11 wherein the second plurality of parallel lines of light are generally perpendicular to the first pattern of parallel lines of light.

14. The method of claim 9 further comprising determining an estimate of a distance between the photography subsystem and the object to be scanned.

15. A computer readable medium containing computer-executable instructions that, when performed by an image signal processor in a mobile communication device having a photography subsystem, a first light source and a second light source, cause the image signal processor to:
send an instruction to activate the first light source to illuminate an object to be scanned with a first pattern of collimated light;
send an instruction to a photography subsystem to obtain a first image of the object to be scanned as illuminated by the first light source;
receive, from the photography subsystem, the first image;
send an instruction to activate a second light source to illuminate the object to be scanned with a second pattern of collimated light, the second pattern of collimated light being offset from the first pattern of collimated light;
send an instruction to the photography subsystem to obtain a second image of the object to be scanned as illuminated by the second light source;
receive, from the photography subsystem, the second image; and
construct a three-dimensional image from the first image and the second image.

16. A light emitting diode (LED) module comprising:
a main module body adapted to emit light;
a low angle lens arranged to focus the light from the main module body to a light beam; and
a top cover adapted to diffuse the light beam in a pattern of collimated light.

17. The LED module of claim 16 wherein the main module body comprises Gallium Nitride.

18. The LED module of claim 16 wherein the low angle lens comprises a molded polymer structure.

19. The LED module of claim 16 wherein the top cover includes a plurality of directional lenses adapted to diffuse the light beam into the pattern of light.
